(19) United States
(12) Patent Application Publication
(10) Pub. No.: US 2016/0020247 A1
(43) Pub. Date: Jan. 21, 2016

(54) SOLID-STATE IMAGE SENSOR, MANUFACTURING METHOD, AND ELECTRONIC DEVICE

(71) Applicant: SONY CORPORATION, Tokyo (JP)

(72) Inventor: Hiroyuki OHRI, Kanagawa (JP)

(21) Appl. No.: 14/773,260

(22) PCT Filed: Feb. 28, 2014
(86) PCT No.: PCT/JP2014/055006

§ 371 Date: Sep. 4, 2015

(30) Foreign Application Priority Data
Mar. 12, 2013 (JP) 2013-048998

(51) Int. Cl. H01L 27/146

(52) U.S. Cl. CPC H01L 27/14689; H01L 27/14612; H01L 27/14643

(57) ABSTRACT

There is provided a solid-state image sensor including a substrate including a photoelectric conversion element that generates an electric charge according to a light amount of an incoming light and accumulates the electric charge inside, an electric charge retaining region that retains the electric charge accumulated by the photoelectric conversion element, and a transfer path that transfers the electric charge accumulated by the photoelectric conversion element to the electric charge retaining region. The photoelectric conversion element, the electric charge retaining region, and the transfer path are located in a perpendicular direction to the substrate.

### TECHNICAL FIELD

The present disclosure relates to a solid-state image sensor, a manufacturing method, and an electronic device, and particularly to a solid-state image sensor, a manufacturing method, and an electronic device that highly accurately control an impurity concentration in a transfer direction of a transfer path for transferring electric charge from a photoelectric conversion element to an electric charge retaining region.

### BACKGROUND ART

A solid-state image sensor is used in an image capturing device such as a digital still camera and a video camera, and an electronic device such as a portable terminal device having an image capturing function, for example. The solid-state image sensor is, for example, a complementary MOS (CMOS) image sensor that reads an electric charge accumulated in a photo diode which is a photoelectric conversion element, via a metal oxide semiconductor (MOS) transistor. In particular, a CMOS image sensor, which is referred to as an active pixel sensor (APS), including an amplification element for each pixel is widely utilized.

In the CMOS image sensor, a read operation for reading electric charge accumulated in a photo diode is typically executed for each row of a pixel array, and a pixel that has finished the read operation repeatedly starts accumulating electric charge from the end time point. As described above, when the read operation is performed for each row of the pixel array, the accumulation period of electric charge is not synchronized in all pixels, causing a distortion in a captured image when a subject is moving, for example. For example, when an image of a subject extending straight in the vertical direction and moving in the lateral direction is captured, the subject tilts in the captured image.

Thus, in order to prevent the occurrence of this distortion, a CMOS image sensor having all pixel simultaneous electronic shutter for making light exposure periods of respective pixels identical is developed. All pixel simultaneous electronic shutter is a function for performing an operation that simultaneously starts light exposure in all pixels effective in image capturing and simultaneously ends the light exposure, and is also referred to as global shutter (global light exposure). As the method for achieving the global light exposure, there are a mechanical method and an electrical method.

In the mechanical method, an openable and closable mechanical shutter that shades a surface of a CMOS image sensor is utilized, for example. That is, in this method, the CMOS image sensor opens the mechanical shutter to start the light exposure in all pixels simultaneously and closes the mechanical shutter to simultaneously shade all pixels at the light exposure period end time point, in order to synchronize the light exposure periods at all pixels.

On the other hand, in the electrical method, an electric charge retaining region provided between a photo diode and a floating diffusion region of each pixel is utilized. That is, in this method, the CMOS image sensor causes the electric charge retaining region to temporarily retain the electric charge accumulated in the photo diode when ending the light exposure period, so that the read of the accumulated electric charge and the start of the light exposure period are timed differently from each other, and the light exposure periods are synchronized in all pixels.

As described above, in the electrical method, it is necessary that the electric charge retaining region is newly provided for each pixel, and therefore the area of the photo diode is made smaller, and the maximum electric charge amount that can be accumulated in the photo diode decreases.

Thus, the applicant of the present application has been proposed a pixel structure in which the photo diode and the electric charge retaining region are integrated through an overflow path, in order to prevent the decrease of the maximum electric charge amount that can be accumulated in the photo diode (for example, refer to Patent Literature 1).

### CITATION LIST

### Patent Literature

Patent Literature 1: JP 2011-216672A

### SUMMARY OF INVENTION

### Technical Problem

In the technology described in Patent Literature 1, a photo diode, a transfer path for transferring an electric charge from a photo diode to an electric charge retaining region, and an electric charge retaining region are located in a horizontal direction relative to a substrate. Thus, the electric charge transfer direction from the photo diode to the electric charge retaining region is the horizontal direction to the substrate.

Here, when manufacturing the CMOS image sensor, an error occurs in the control of a position of ion doping in the horizontal direction relative to the substrate, due to the variation of resist processing. Thus, it is difficult to control the impurity concentration of the transfer path in the transfer direction with high degree of accuracy.

As a result, the potential barrier of the transfer path is different in each individual piece, and the saturation electric charge amount of the photo diode is different. This is more remarkable as a pixel size is smaller.

The present disclosure is made in view of the above situation, and highly accurately controls the impurity concentration in the transfer direction of the transfer path for transferring the electric charge from the photoelectric conversion element to the electric charge retaining region.

### Solution to Problem

A solid-state image sensor according to a first aspect of the present disclosure includes: a substrate including a photoelectric conversion element that generates an electric charge according to a light amount of an incoming light and accumulates the electric charge inside, an electric charge retaining region that retains the electric charge accumulated by the photoelectric conversion element, and a transfer path that transfers the electric charge accumulated by the photoelectric conversion element to the electric charge retaining region. The photoelectric conversion element, the electric charge retaining region, and the transfer path are located in a perpendicular direction to the substrate.

According to the first aspect of the present disclosure, the photoelectric conversion element included in the substrate generates an electric charge according to a light amount of an incoming light and accumulates the electric charge inside, the electric charge retaining region retains the electric charge accumulated by the photoelectric conversion element, and the transfer path transfers the electric charge accumulated by the photoelectric conversion element to the electric charge retaining region. The photoelectric conversion element, the electric charge retaining region, and the transfer path are located in a perpendicular direction to the substrate.

A manufacturing method according to a second aspect of the present disclosure includes: a photoelectric conversion element formation step for forming a photoelectric conversion element that generates an electric charge according to a light amount of an incoming light and accumulates the electric charge inside, in a substrate, by means of a manufacturing equipment of a solid-state image sensor; an electric charge retaining region formation step for forming an electric charge retaining region that retains the electric charge accumulated by a photoelectric conversion element, in the substrate, in such a manner that the photoelectric conversion element and the electric charge retaining region are located in a perpendicular direction to the substrate, by means of the manufacturing equipment of the solid-state image sensor; and a transfer path formation step for forming a transfer path that transfers the electric charge accumulated by the photoelectric conversion element to the electric charge retaining region, in the substrate, in such a manner that the photoelectric conversion element and the transfer path are located in a perpendicular direction to the substrate, by means of the manufacturing equipment of the solid-state image sensor.

According to the second aspect of the present disclosure, a photoelectric conversion element that generates an electric charge according to a light amount of an incoming light and accumulates the electric charge inside, is formed in a substrate, by means of a manufacturing equipment of a solid-state image sensor; an electric charge retaining region that retains the electric charge accumulated by a photoelectric conversion element, is formed in the substrate, in such a manner that the photoelectric conversion element and the electric charge retaining region are located in a perpendicular direction to the substrate, by means of the manufacturing equipment of the solid-state image sensor; and a transfer path that transfers the electric charge accumulated by the photoelectric conversion element to the electric charge retaining region, is formed in the substrate, in such a manner that the photoelectric conversion element and the transfer path are located in a perpendicular direction to the substrate, by means of the manufacturing equipment of the solid-state image sensor.

An electronic device according to a third aspect of the present disclosure includes: a substrate including a photoelectric conversion element that generates an electric charge according to a light amount of an incoming light and accumulates the electric charge inside, an electric charge retaining region that retains the electric charge accumulated by the photoelectric conversion element, and a transfer path that transfers the electric charge accumulated by the photoelectric conversion element to the electric charge retaining region. The photoelectric conversion element, the electric charge retaining region, and the transfer path are located in a perpendicular direction to the substrate.

According to the third aspect of the present disclosure, the photoelectric conversion element included in the substrate generates an electric charge according to a light amount of an incoming light and accumulates the electric charge inside, the electric charge retaining region retains the electric charge accumulated by the photoelectric conversion element, and the transfer path transfers the electric charge accumulated by the photoelectric conversion element to the electric charge retaining region. The photoelectric conversion element, the electric charge retaining region, and the transfer path are located in a perpendicular direction to the substrate.

### Advantageous Effects of Invention

According to the first and third aspect of the present disclosure, the impurity concentration is controlled highly accurately in the transfer direction of the transfer path for transferring the electric charge from the photoelectric conversion element to the electric charge retaining region.

Also, according to the second aspect of the present disclosure, a solid-state image sensor that highly accurately controls the impurity concentration in the transfer direction of the transfer path for transferring the electric charge from the photoelectric conversion element to the electric charge retaining region is manufactured.

### BRIEF DESCRIPTION OF DRAWINGS

FIG. 1 is a block diagram illustrating an exemplary configuration of a first embodiment of a CMOS image sensor as a solid-state image sensor to which the present disclosure is applied.

FIG. 2 is a plan view illustrating a first exemplary configuration of a pixel of a pixel array unit of FIG. 1.

FIG. 3 is an A-A′ cross-sectional view of a pixel of FIG. 2.

FIG. 4 is a B-B′ cross-sectional view of a pixel of FIG. 2.

FIG. 5 is a C-C′ cross-sectional view of a pixel of FIG. 2.

FIG. 6 is a D-D′ cross-sectional view of a pixel of FIG. 2.

FIG. 7 is an E-E′ cross-sectional view of a pixel of FIG. 2.

FIG. 8 is a diagram illustrating a transfer flow of electric charge from a photo diode to a memory unit of FIG. 3.

FIG. 9 is a diagram illustrating a transfer flow of electric charge from a photo diode to a memory unit of FIG. 4.

FIG. 10 is a diagram illustrating a transfer flow of electric charge from a photo diode to a memory unit of FIG. 5.

FIG. 11 is a diagram illustrating a transfer flow of electric charge from a memory unit to a floating diffusion region of FIG. 3.

FIG. 12 is a diagram illustrating a transfer flow of electric charge from a memory unit to a floating diffusion region of FIG. 7.

FIG. 13 is a diagram describing a first example of a manufacturing method of a pixel of FIG. 3 by a manufacturing equipment.

FIG. 14 is a diagram describing a first example of a manufacturing method of a pixel of FIG. 3 by a manufacturing equipment.

FIG. 15 is a diagram describing a second example of a manufacturing method of a pixel of FIG. 3 by a manufacturing equipment.

FIG. 16 is a diagram describing a second example of a manufacturing method of a pixel of FIG. 3 by a manufacturing equipment.

FIG. 17 is a diagram describing a third example of a manufacturing method of a pixel of FIG. 3 by a manufacturing equipment.

FIG. 18 is a diagram describing a third example of a manufacturing method of a pixel of FIG. 3 by a manufacturing equipment.

FIG. 19 is an A-A′ cross-sectional view of a second exemplary configuration of a pixel of a pixel array unit of FIG. 1.

FIG. 20 is an A-A′ cross-sectional view illustrating a first exemplary configuration of a pixel of a second embodiment of a CMOS image sensor as a solid-state image sensor to which the present disclosure is applied.

FIG. 21 is a diagram illustrating a transfer flow of electric charge from a memory unit to a floating diffusion region of FIG. 20.

FIG. 22 is a diagram describing an example of a manufacturing method of a pixel of FIG. 20 by a manufacturing equipment.

FIG. 23 is a diagram describing an example of a manufacturing method of a pixel of FIG. 20 by a manufacturing equipment.

FIG. 24 is an A-A′ cross-sectional view illustrating a second exemplary configuration of a pixel of a second embodiment of a CMOS image sensor as a solid-state image sensor to which the present disclosure is applied.

FIG. 25 is a plan view illustrating an exemplary configuration of a pixel of a third embodiment of a CMOS image sensor as a solid-state image sensor to which the present disclosure is applied.

FIG. 26 is a D-D′ cross-sectional view of a pixel of FIG. 25.

FIG. 27 is a block diagram illustrating an exemplary configuration of an image capturing device as an electronic device to which the present disclosure is applied.

### DESCRIPTION OF EMBODIMENTS

### First Embodiment

### Exemplary Configuration of First Embodiment of Solid-State Image Sensor

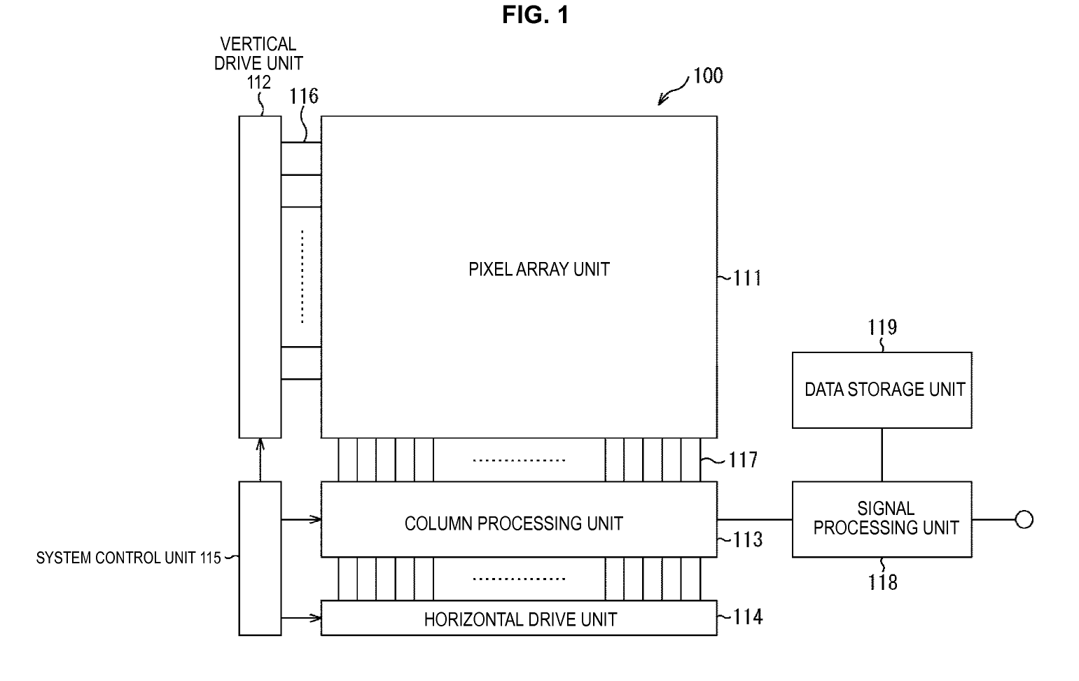

FIG. 1 is a block diagram illustrating an exemplary configuration of the first embodiment of a CMOS image sensor as a solid-state image sensor to which the present disclosure is applied.

The CMOS image sensor 100 includes a pixel array unit 111, a vertical drive unit 112, a column processing unit 113, a horizontal drive unit 114, a system control unit 115, a pixel drive lines 116, a vertical signal lines 117, a signal processing unit 118, and a data storage unit 119.

The pixel array unit 111, the vertical drive unit 112, the column processing unit 113, the horizontal drive unit 114, the system control unit 115, the pixel drive lines 116, the vertical signal lines 117, the signal processing unit 118, and the data storage unit 119 are formed in an undepicted semiconductor substrate (chip).

It may be such that the CMOS image sensor 100 does not include the signal processing unit 118 and the data storage unit 119, and the signal processing unit 118 and the data storage unit 119 are provided as an outside signal processing unit such as a digital signal processor (DSP) in a semiconductor substrate different from the CMOS image sensor 100, for example.

The CMOS image sensor 100 captures an image including no distortion, by the global light exposure.

Specifically, in the pixel array unit 111, pixels having a photoelectric conversion element that generates electric charge of an electric charge amount according to a light amount of incoming light and accumulates the electric charge inside are located two-dimensionally in the form of matrix.

Also, in the pixel array unit 111, the pixel drive lines 116 are formed in the left-right direction (row direction) of the drawing for respective rows for the pixels in the form of matrix, and the vertical signal lines 117 are formed in the upward-downward direction (column direction) of the drawing for each column One ends of the pixel drive lines 116 are connected to output terminals corresponding to the respective rows of the vertical drive unit 112.

The vertical drive unit 112 is configured by a shift register, an address decoder, and others, and is a pixel drive unit that drives all pixels of the pixel array unit 111 simultaneously or pixels of each row. Although depiction of a specific configuration of this vertical drive unit 112 is omitted, the vertical drive unit 112 includes three scanning system consisting of a readout scanning system, a retention scanning system, and a sweep scanning system.

The retention scanning system simultaneously outputs transfer pulses from the output terminals connected to the pixel drive lines 116 of all rows, in order to transfer and retain the electric charge accumulated in the photoelectric conversion element. The readout scanning system selects each row in order so as to read a pixel signal corresponding to the retained electric charge of each row in order, and outputs a selection pulse from the output terminal connected to the pixel drive line 116 of the selected row.

The sweep scanning system simultaneously outputs control pulses from the output terminals connected to the pixel drive lines 116 of all rows ahead of the scan of the retention scanning system by the shutter speed time, in order to sweep (reset) unnecessary electric charge from the photoelectric conversion element. With the scan by the sweep scanning system, what is called electronic shutter operation is performed at all pixels simultaneously. Here, the electronic shutter operation refers to an operation that discards the electric charge of the photoelectric conversion element and newly starts light exposure (start accumulation of electric charge).

With the above drive, the pixel signals of all pixels read by the readout scanning system correspond to the electric charge accumulated during the shutter speed time from the electronic shutter operation to the scan by the retention scanning system. That is, the accumulation periods of electric charge (light exposure periods) in all pixels are same.

The pixel signal output from each pixel of the row selected by the readout scanning system of the vertical drive unit 112 is supplied to the column processing unit 113 through each of the vertical signal lines 117.

The column processing unit 113 includes signal processing circuits for respective columns of the pixel array unit 111. Each signal processing circuit of the column processing unit 113 performs the denoising process such as correlated double sampling (CDS) process, and the signal processing such as the A/D conversion process, on the pixel signal output from each pixel of the selected row through the vertical signal lines 117. With the CDS process, fixed pattern noise unique to pixel, such as reset noise and threshold value variation of amplification transistors, is removed. The column processing unit 113 temporarily retains the pixel signal after the signal processing.

The horizontal drive unit 114 is configured by a shift register, an address decoder, and others, and selects the signal processing circuits of the column processing unit 113 in order. With the selection scan by the horizontal drive unit 114, the pixel signal processed in each signal processing circuit of the column processing unit 113 is output to the signal processing unit 118 in order.

The system control unit 115 is configured by a timing generator for generating various types of timing signals and others, and controls the vertical drive unit 112, the column processing unit 113, and the horizontal drive unit 114 on the basis of the various types of timing signals generated in the timing generator.

The signal processing unit 118 includes an addition processing function at least. The signal processing unit 118 performs various signal processing, such as an addition process, to the pixel signal output from the column processing unit 113. In this case, the signal processing unit 118 stores an intermediate result and the like of the signal processing in the data storage unit 119 as necessary, and refers to it at a necessary time. The signal processing unit 118 outputs the pixel signal after the signal processing.

### (First Exemplary Configuration of Pixel)

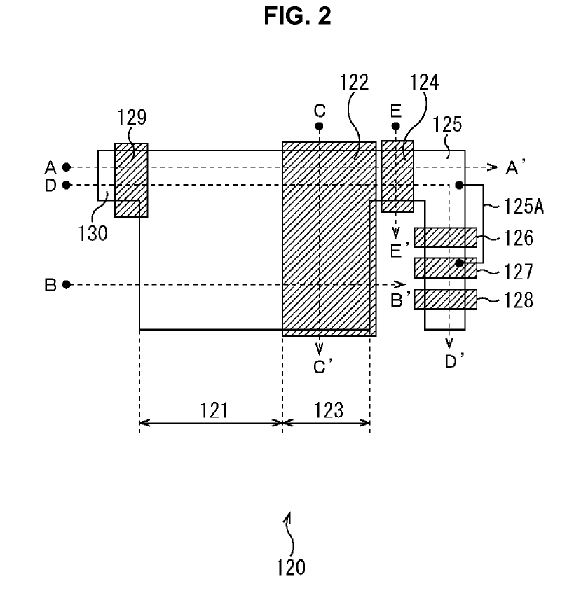

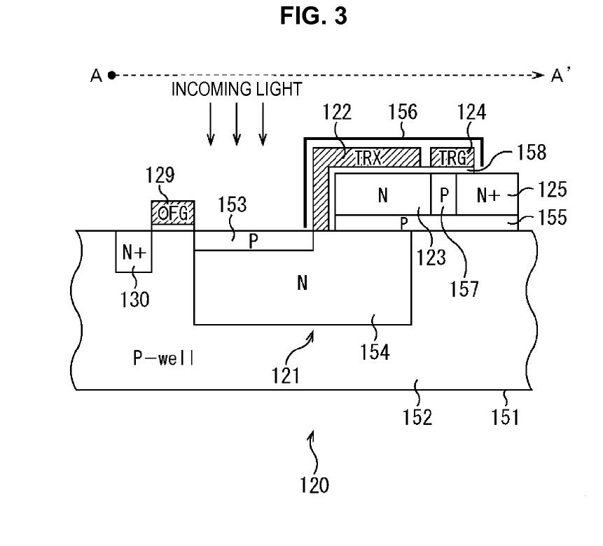

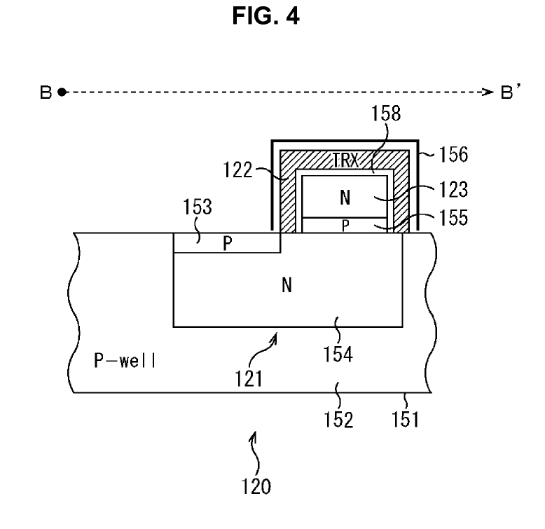

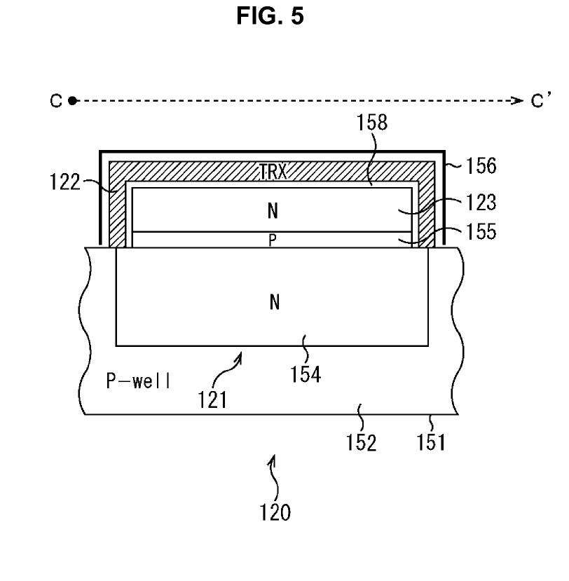

FIG. 2 is a plan view illustrating the first exemplary configuration of the pixel located in the form of matrix in the pixel array unit 111 of FIG. 1. Also, FIG. 3 to FIG. 7 are the A-A′ cross-sectional view, the B-B′ cross-sectional view, the C-C′ cross-sectional view, the D-D′ cross-sectional view, the E-E cross-sectional view of the pixel of FIG. 2, respectively.

As illustrated in FIG. 2, the pixel 120 includes a photo diode (PD) 121, a first transfer gate (TRX) 122, a memory unit (MEM) 123, a second transfer gate (TRG) 124, and a floating diffusion region (FD) 125.

Also, the pixel 120 includes a reset transistor (RST) 126, an amplification transistor (AMP) 127, and a selection transistor 128 (SEL), and the floating diffusion region 125 and the amplification transistor 127 are connected to each other by an FD line 125A. Also, the pixel 120 includes a third transfer gate (OFG) 129 and an electric charge discharge region (OFD) 130.

As illustrated in FIG. 3 and other drawings, the photo diode 121 has the hole accumulation diode (HAD) structure, and is formed in a silicon substrate 151 as a semiconductor substrate in which the pixel array unit 111 is located. Specifically, the photo diode 121 is formed such that a P-type layer 153 is embedded on a front face of the silicon substrate 151, and an N-type layer 154 is embedded so as to cover one side face of the P-type layer 153, in a P-type well layer 152 formed in the silicon substrate 151.

Note that, here, the surface on which the P-type layer 153 of the silicon substrate 151 is provided is referred to as the front face of the silicon substrate 151, and the surface opposite to the front face is referred to as the back face. Also, the surface in the perpendicular direction to the front face and the back face is referred to as a side face. Also, the front face side of the silicon substrate 151 is referred to as an upper side, and the back face side is referred to as a lower side, as appropriate.

The photo diode 121 generates the electric charge of the electric charge amount according to the light amount of the light that enters from the front face side of the silicon substrate 151, and accumulates the electric charge inside.

As illustrated in FIG. 3 and other drawings, the memory unit 123 is an N-type layer located in the perpendicular direction to the silicon substrate 151, with a P-type layer 155 sandwiched in relation to the photo diode 121. Specifically, the memory unit 123 and the P-type layer 155 are stacked in the order of the P-type layer 155 and the memory unit 123 on the silicon substrate 151 in which the N-type layer 154 is embedded.

As described above, the memory unit 123 and the photo diode 121 are located in the perpendicular direction to the silicon substrate 151, and therefore the photo diode 121 can be set to the same size as when the memory unit 123 does not exist. Also, the size of the memory unit 123 is set to a sufficient size.

In contrast, when the memory unit and the photo diode are located in the horizontal direction in relation to the silicon substrate, the size of the photo diode needs to be made smaller by the size of the memory unit. As a result, the saturation electric charge amount of the photo diode decreases. Also, it is difficult to set the size of the memory unit at a sufficient size, and the electric charge amount that the memory unit can retain decreases.

Also, the N-type layer 154 of the photo diode 121 extends at the lower portion of the memory unit 123, and thus, even when light enters into the pixel 120 obliquely, the unnecessary electric charge is prevented from entering into the memory unit 123.

In contrast, when the memory unit and the photo diode are located in the horizontal direction in relation to the silicon substrate, and light enters into the pixel obliquely, a part of electric charge generated by the photoelectric conversion in a comparatively deep region below the memory unit happens to enter the memory unit. This electric charge is read from the memory unit in the same way as the electric charge transferred from the photo diode, as noise.

The P-type layer 155 is a barrier for separating the photo diode 121 and the memory unit 123 electrically. The side face of the P-type layer 155 functions as a transfer path for transferring the electric charge accumulated in the photo diode 121 to the memory unit 123, when a transfer pulse (a sufficient voltage to conduct between the photo diode 121 and the memory unit 123) is applied to the first transfer gate 122. Also, the memory unit 123 is an electric charge retaining region for retaining the electric charge transferred via the P-type layer 155 from the photo diode 121.

As illustrated in FIG. 3 and other drawings, the first transfer gate 122 is formed to cover the side face and the front face of the stacked memory unit 123 and the P-type layer 155, via a gate insulating film 158. When the transfer pulse is applied to the first transfer gate 122 from the vertical drive unit 112 via the pixel drive line 116, the P-type layer 155 changes into a conductive state, and the electric charge accumulated in the photo diode 121 is transferred to the memory unit 123.

Note that, as illustrated in FIG. 3 and other drawings, the front face and the side face of the first transfer gate 122 are covered by a shading film 156 made of tungsten or the like.

As illustrated in FIG. 3 and other drawings, the floating diffusion region 125 is an N-type layer stacked on the P-type layer 155 at the same height as the memory unit 123. That is, the memory unit 123 and the floating diffusion region 125 are located in the horizontal direction in relation to the silicon substrate 151.

Between the floating diffusion region 125 and the memory unit 123, there is formed a P-type layer 157 which is a barrier for separating the floating diffusion region 125 and the memory unit 123 electrically. The side face of the P-type layer 157 functions as a transfer path for transferring the electric charge accumulated in the memory unit 123 to the floating diffusion region 125 when the transfer pulse is applied to a second transfer gate 124. Also, the floating diffusion region 125 is an electric charge voltage conversion unit that converts to the voltage the electric charge transferred from the memory unit 123 via the P-type layer 155.

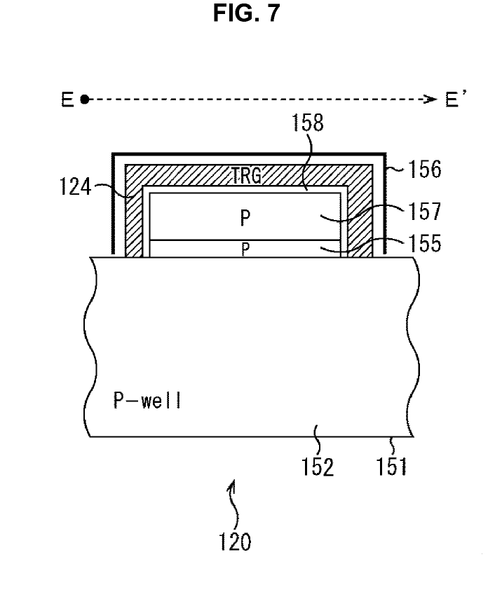

As illustrated in FIG. 3 and FIG. 7 and other drawings, the second transfer gate 124 is formed to cover the front face and the side face of the floating diffusion region 125 and the P-type layer 157, via the gate insulating film 158. When the transfer pulse is applied to the second transfer gate 124 from the vertical drive unit 112 via the pixel drive line 116, the P-type layer 157 changes into a conductive state, and the electric charge retained in the memory unit 123 is transferred to the floating diffusion region 125. Note that, as illustrated in FIG. 3 and other drawings, the front face and the side face of the second transfer gate 124 is covered by the shading film 156.

In the pixel 120, the memory unit 123 and the P-type layer 155 are provided on the silicon substrate 151, and therefore the front face and the side face of the memory unit 123 and the P-type layer 155 are covered with the shading film 156, as described above. Thus, the light that enters into the pixel 120 is prevented from entering into the memory unit 123.

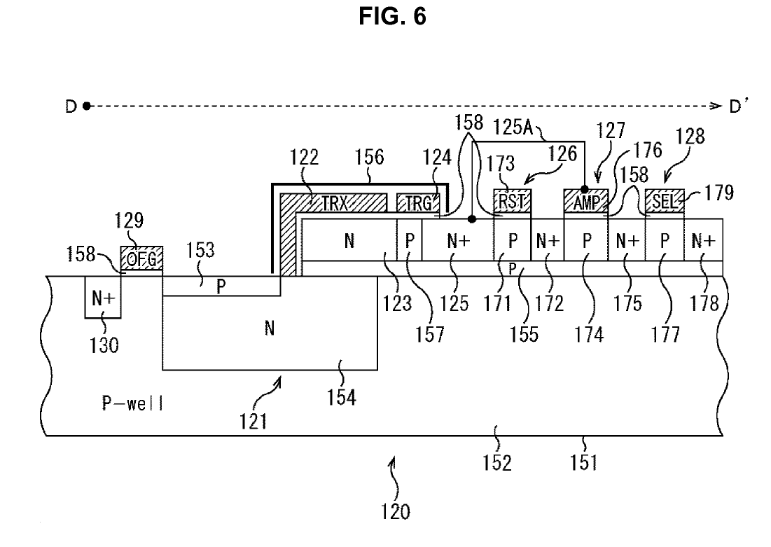

As illustrated in FIG. 6, the reset transistor 126, the amplification transistor 127, and the selection transistor 128 are MOS transistors of N channel. That is, the reset transistor 126 is configured by a part of the floating diffusion region 125, a part of an N-type layer 172, a P-type layer 171 sandwiched between the floating diffusion region 125 and the N-type layer 172, and a gate 173 that covers the P-type layer 171 via the gate insulating film 158.

Also, the amplification transistor 127 is configured by a part of the N-type layer 172, a part of an N-type layer 175, a P-type layer 174 sandwiched between the N-type layer 172 and the N-type layer 175, and a gate 176 that covers the P-type layer 174 via the gate insulating film 158. The selection transistor 128 is configured by a part of the N-type layer 175, a part of an N-type layer 178, a P-type layer 177 sandwiched between the N-type layer 175 and the N-type layer 178, and a gate 179 that covers the P-type layer 177 via the gate insulating film 158.

The reset transistor 126, the amplification transistor 127, and the selection transistor 128 are stacked on the P-type layer 155. A power supply VDB is connected to the N-type layer 172, and the vertical signal line 117 of FIG. 1 is connected to the N-type layer 178. Also, the gate 173 and the gate 179 are connected to the vertical drive unit 112 via the pixel drive line 116 of FIG. 1, and the gate 176 is connected to the floating diffusion region 125 via the FD line 125A.

When the reset pulse RST is applied to the gate 173 via the pixel drive line 116, the reset transistor 126 resets the floating diffusion region 125. The amplification transistor 127 amplifies the voltage of the floating diffusion region 125 connected to the gate 176.

When the selection pulse SEL is applied to the gate 179 via the pixel drive line 116, the selection transistor 128 supplies the signal of the voltage amplified by the amplification transistor 127 as a pixel signal, to the column processing unit 113 via the vertical signal line 117.

Also, as illustrated in FIG. 6 and other drawings, a third transfer gate 129 is formed on the silicon substrate 151 via the gate insulating film 158, not overlapping but adjacent to the photo diode 121. Also, an electric charge discharge region 130 is an N-type layer (N+) embedded in the silicon substrate 151, adjacent to the third transfer gate 129.

The third transfer gate 129 transfers the electric charge accumulated in the photo diode 121 to the electric charge discharge region 130, when a control pulse OFG is applied via the pixel drive line 116 by the vertical drive unit 112 when starting the light exposure. The electric charge discharge region 130 discharges the electric charge transferred from the photo diode 121 by the third transfer gate 129.

In the pixel 120 configured described above as, the photo diode 121 generates electric charge of the electric charge amount according to the light amount of the light that enters from the front face side of the silicon substrate 151, and accumulates the electric charge inside. When a light exposure open time arrives, the vertical drive unit 112 simultaneously applies the control pulse OFG to the third transfer gates 129 of all pixels via the pixel drive lines 116. Thereby, the electric charge accumulated in the photo diode 121 is discharged to the electric charge discharge region 130, and the accumulation (the light exposure) of electric charge by the photo diode 121 is started.

Then, at the light exposure end time after elapsing the shutter speed time from the light exposure start time, the vertical drive unit 112 simultaneously applies the transfer pulse to the first transfer gates 122 of all pixels via the pixel drive lines 116. Thereby, the P-type layer 155 changes into a conductive state, and the electric charge accumulated in the photo diode 121 is transferred to the memory unit 123 via the P-type layer 155, in order to end the light exposure.

Thereafter, the vertical drive unit 112 selects in the order each row, and applies the selection pulse SEL to the selection transistor 128 of the selected row via the pixel drive line 116, and applies the reset pulse RST to the reset transistor 126 via the pixel drive line 116. Thereby, the electric charge retained in the floating diffusion region 125 is discharged (reset). Also, the voltage of the floating diffusion region 125 when resetting is amplified by the amplification transistor 127, and is output to the column processing unit 113 as an offset component of the pixel signal via the vertical signal line 117.

Thereafter, the vertical drive unit 112 applies the transfer pulse to the second transfer gate 124 of the selected row via the pixel drive line 116. Thereby, the P-type layer 157 changes into a conductive state, and the electric charge retained in the memory unit 123 is transferred to the floating diffusion region 125 via the P-type layer 157.

In this case, the reset pulse RST is not applied to the reset transistor 126, the amplification transistor 127 amplifies the voltage of the floating diffusion region 125 connected to the gate 176. Also, in this case, the selection pulse SEL keeps being applied to the selection transistor 128, and the signal of the voltage amplified by the amplification transistor 127 is output to the column processing unit 113 via the vertical signal line 117 as the pixel signal.

As described above, the pixel signal of the image for which the global light exposure is performed is supplied to the column processing unit 113 row by row. As a result, the pixel signal of the image for which the global light exposure is performed is output to the signal processing unit 118 in the order of raster scan.

### (Transfer Flow of Electric Charge)

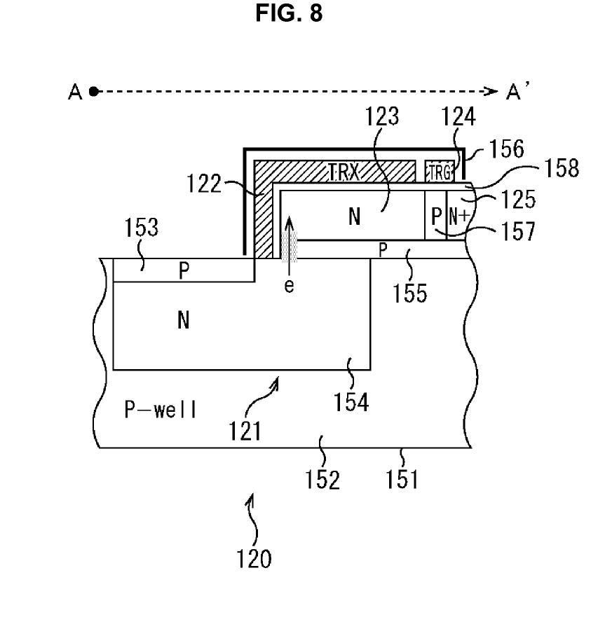

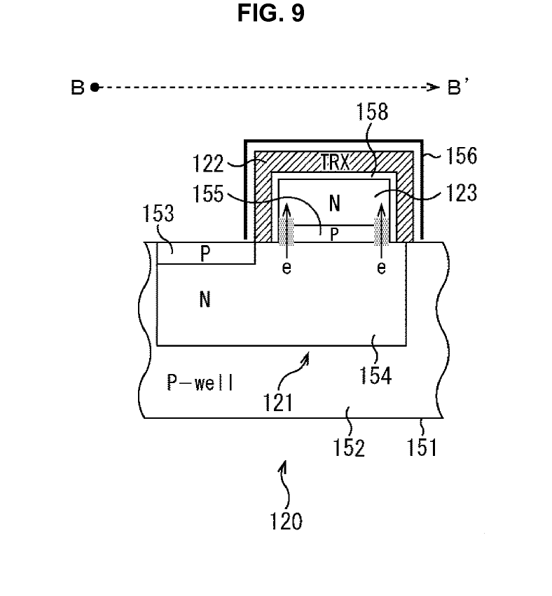

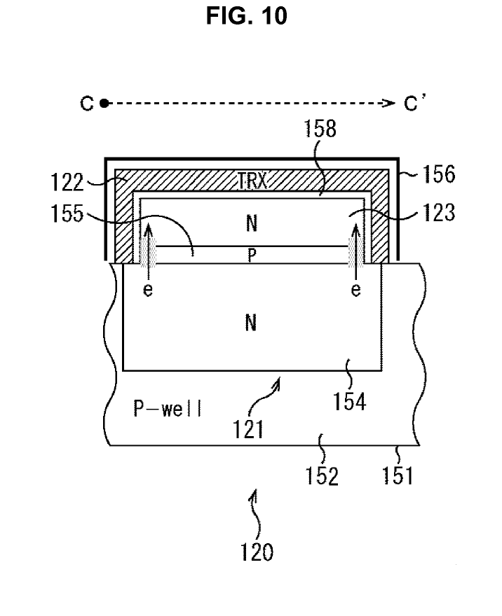

FIG. 8 to FIG. 10 is a diagram illustrating a transfer flow of electric charge from the photo diode 121 to the memory unit 123.

When a negative voltage necessary for accumulating electron holes on the front face and the side face of the memory unit 123 is applied to the first transfer gate 122, a potential barrier is formed by the P-type layer 155, and the interconnection between the photo diode 121 and the memory unit 123 changes into a non-conductive state. Thereby, the photo diode 121 and the memory unit 123 are separated electrically.

On the other hand, as illustrated in FIG. 8 to FIG. 10, when the transfer pulse is applied to the first transfer gate 122, an inversion layer is formed on the side face of the P-type layer 155, and the interconnection between the photo diode 121 and the memory unit 123 changes into a conductive state. Thereby, the electric charge accumulated in the photo diode 121 is transferred in the perpendicular direction to the silicon substrate 151, and is supplied to the memory unit 123. In the present embodiment, at least two transfer paths from the photo diode 121 to the memory unit 123 are formed along the side face of the P-type layer 155.

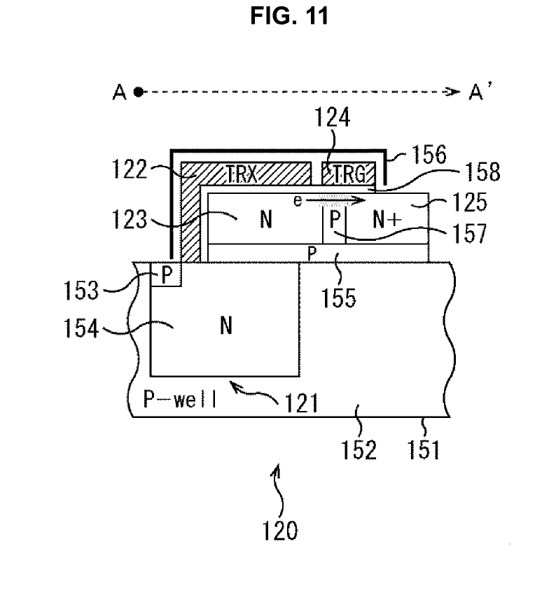

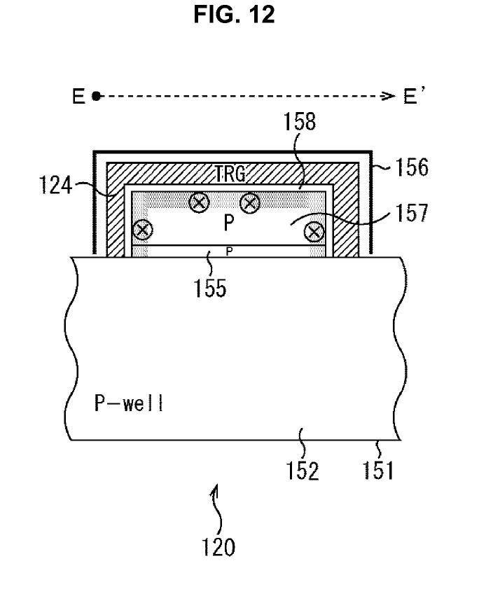

FIGS. 11 and 12 is a diagram illustrating a transfer flow of electric charge from the memory unit 123 to the floating diffusion region 125.

When a negative voltage necessary for accumulating electron holes on the front face and the side face of the floating diffusion region 125 is applied to the second transfer gate 124, a potential barrier is formed by the P-type layer 157, and the interconnection between the memory unit 123 and the floating diffusion region 125 changes into a non-conductive state. Thereby, the memory unit 123 and the floating diffusion region 125 are separated electrically.

On the other hand, as illustrated in FIGS. 11 and 12, when the transfer pulse is applied to the second transfer gate 124, an inversion layer is formed on the front face of the P-type layer 157, and the interconnection between the memory unit 123 and the floating diffusion region 125 changes into a conductive state. Thereby, the electric charge accumulated in the memory unit 123 is transferred in the horizontal direction in relation to the silicon substrate 151, and is supplied to the floating diffusion region 125.

### (First Example of Manufacturing Method of Pixel)

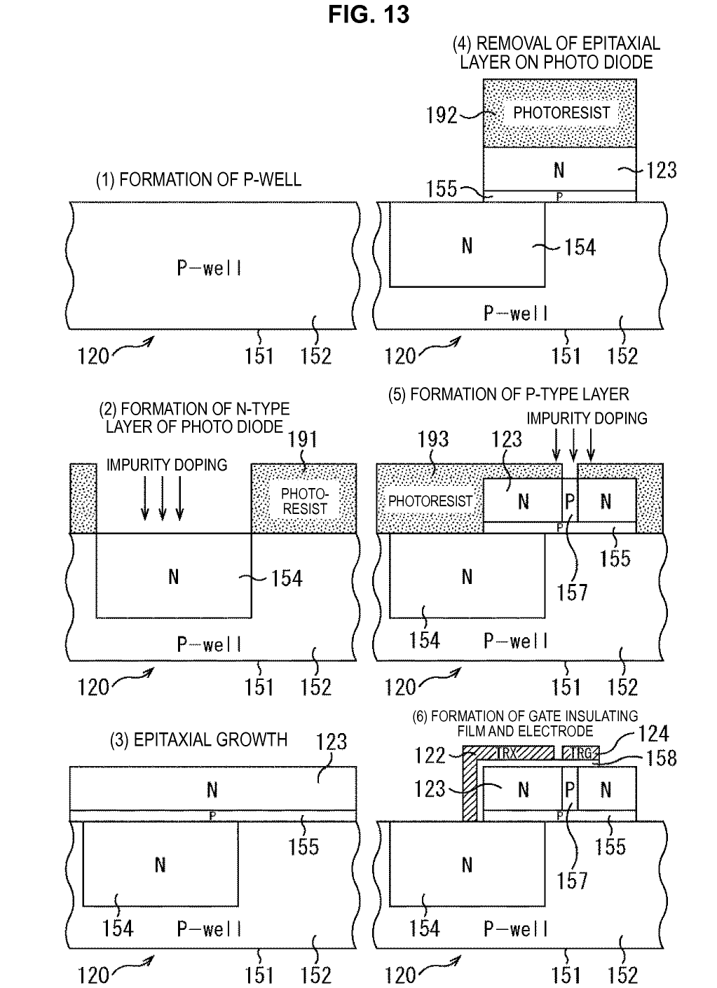

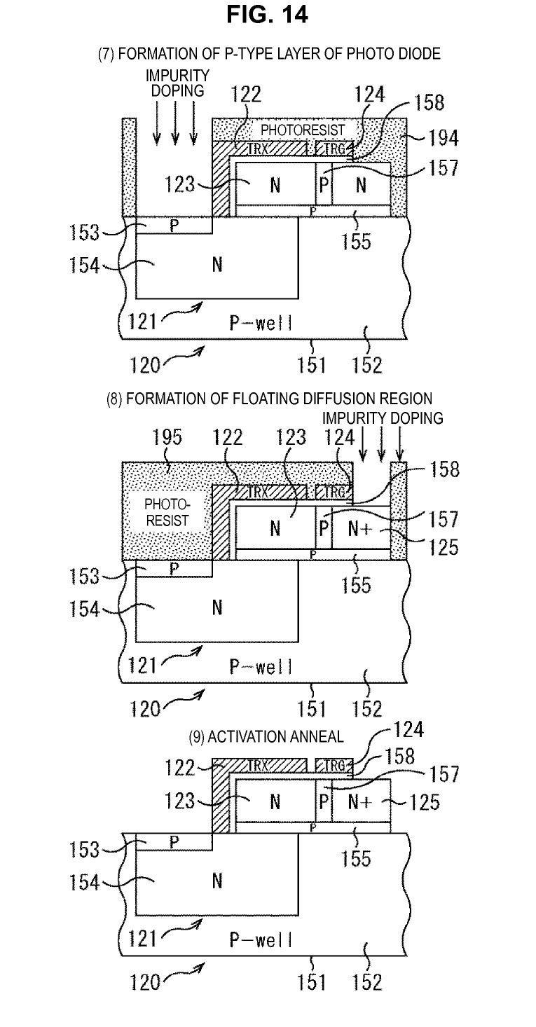

With reference to FIGS. 13 and 14, the first example of the manufacturing method of the pixel 120 by the manufacturing equipment will be described.

As illustrated in FIG. 13, in the first process, an element separating region is formed (not illustrated in the drawings) by a method such as shallow trench isolation (STI) and local oxidation of silicon (LOCOS) on the silicon (Si) substrate 151. Thereafter, the P-type well layer 152 which has an impurity concentration of 10¹⁶/cm³ to 10¹⁸/cm³ is formed by ion doping.

In the second process, the N-type layer 154 which has an impurity concentration of 10¹⁶/cm³ to 10¹⁸/cm³ is formed, at an inner portion of the silicon substrate 151, by ion doping using a photoresist 191 as a mask.

In the third process, the P-type layer 155 and the memory unit 123 are formed as epitaxial layers, on the silicon substrate 151, by the epitaxial growth method. Specifically, in-situ doping is performed at the time of growth by the epitaxial growth method, to form the P-type layer 155 which has an impurity concentration of 10¹⁶/cm³ to 10¹⁸/cm³, and the N-type layer as the memory unit 123 which has an impurity concentration of 10¹⁶/cm³ to 10¹⁸/cm³. The thickness of the epitaxial layer is equal to or larger than 100 nm, for example.

In the fourth process, the epitaxial layer of the region including a part of the upper portion of the N-type layer 154 is etched, using a photoresist 192 as a mask. That is, the region other than the region where the memory unit 123 and the P-type layer 155 of the epitaxial layer are to be formed is removed. Thereby, the raised step is formed on the front face of the silicon substrate 151.

In the fifth process, the P-type layer 157, the P-type layer 171, the P-type layer 174, and the P-type layer 177, which have an impurity concentration of 10¹⁶/cm³ to 10¹⁸/cm³, are formed, in the memory unit 123, by ion doping using a photoresist 193 as a mask.

In the sixth process, the gate insulating film 158 made of SiO2 is formed on the silicon substrate 151, by the thermal oxidation method. Then, polysilicon and metal are deposited on the gate insulating film 158 by the chemical vapor deposition (CVD) method, and etching is performed using a resist mask, to form the first transfer gate 122, the second transfer gate 124, the gate 173, the gate 176, and the gate 179. The film thicknesses of these gates are 100 nm to 300 nm

As illustrated in FIG. 14, in the seventh process, the P-type layer 153 is formed at the front face side of the inner portion of the silicon substrate 151, by ion doping using a photoresist 194 as a mask.

In the eighth process, the impurity concentration of parts of the memory unit 123 is set within 10¹⁸/cm³ to 10²⁰/cm³ by ion doping using a photoresist 195 as a mask, to make the parts the floating diffusion region 125, the N-type layer 172, the N-type layer 175, and the N-type layer 178.

In the ninth process, activation anneal is performed at approximately 1000° C. Thereafter, the front face and the side face of the first transfer gate 122 and the second transfer gate 124 are covered by the shading film 156, to complete the manufacturing of the pixel 120.

As described above, in the pixel 120, the photo diode 121, the memory unit 123, and the P-type layer 155 are located in the perpendicular direction to the silicon substrate 151, and therefore the transfer direction of electric charge in the P-type layer 155 is the perpendicular direction to the silicon substrate 151. Thus, the impurity concentration of the P-type layer 155 in the transfer direction of electric charge is controlled by the thickness and the concentration of the P-type layer 155. That is, in the manufacturing method of FIGS. 13 and 14, the impurity concentration of the P-type layer 155 in the transfer direction of electric charge is controlled by the thickness and the concentration of the epitaxial layer.

Thereby, the impurity concentration of the P-type layer 155 in the transfer direction of electric charge is controlled highly accurately, as compared with the case in which the impurity concentration of the P-type layer 155 in the transfer direction of electric charge is controlled by the position control in the parallel direction relative to the silicon substrate 151. As a result, the fluctuation of the individual potential barrier formed in the P-type layer 155 is reduced, and the variation of the saturation electric charge amount of the individual photo diode 121 is reduced.

### (Second Example of Manufacturing Method of Pixel)

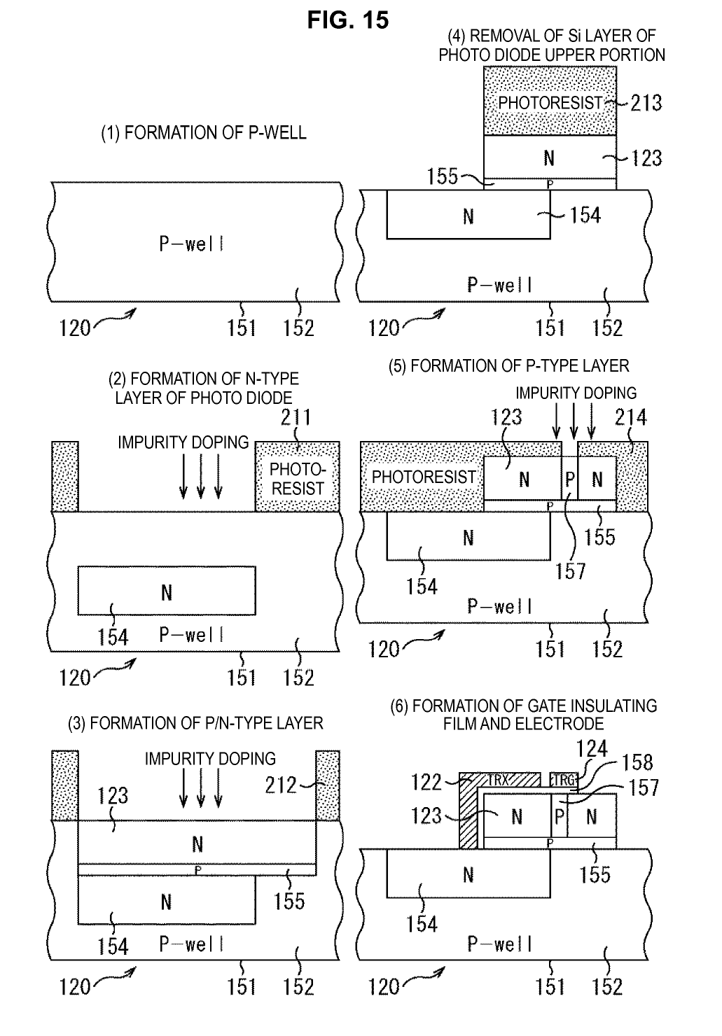

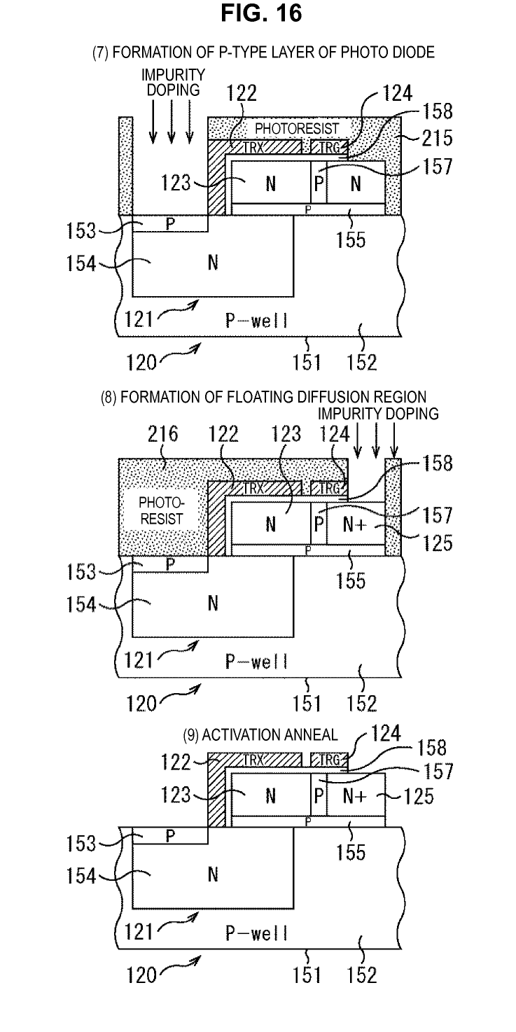

With reference to FIGS. 15 and 16, the second example of the manufacturing method of the pixel 120 by the manufacturing equipment will be described

The manufacturing method of FIGS. 15 and 16 is different from the manufacturing method of FIGS. 13 and 14 in that the P-type layer 155 and the memory unit 123 are not formed by the epitaxial growth method, but formed by ion doping.

Specifically, as illustrated in FIG. 15, in the first process, an element separating region is formed on the silicon substrate 151, and the P-type well layer 152 is formed by ion doping, in the same way as the first process of FIG. 13.

In the second process, the N-type layer 154 which has an impurity concentration of 10¹⁶/cm³ to 10¹⁸/cm³ is formed at the inner portion of the silicon substrate 151, by ion doping using a photoresist 211 as a mask.

In the third process, the P-type layer 155 which has an impurity concentration of 10¹⁶/cm³ to 10¹⁸/cm³ is formed at a portion closer to the front face than the N-type layer 154 at the inner portion of the silicon substrate 151, by ion doping using a photoresist 212 as a mask. Also, the N-type layer as the memory unit 123 which has an impurity concentration of 10¹⁶/cm³ to 10¹⁸/cm³ is formed at the front face side of the P-type layer 155.

In the fourth process, the P-type layer 155 and the memory unit 123 of parts of the upper portion of the N-type layer 154, and the P-type well layer 152 whose position in the perpendicular direction to the silicon substrate 151 is same as the P-type layer 155 and the memory unit 123 are etched, using a photoresist 213 as a mask. That is, the region other than the region where the P-type layer 155 and the memory unit 123 are to be formed, whose position in the perpendicular direction to the silicon substrate 151 is same as the above region, is removed. Thereby, the raised step is formed on the front face of the silicon substrate 151.

The fifth to ninth processes are same as the fifth to ninth processes of FIGS. 13 and 14, and therefore their description will be omitted.

As described above, in the manufacturing method of FIGS. 15 and 16, the impurity concentration of the P-type layer 155 in the transfer direction of electric charge is controlled by the implantation depth and the concentration of ion doping. Thereby, the impurity concentration of the P-type layer 155 in the transfer direction of electric charge is controlled highly accurately, as compared with the case in which the impurity concentration of the P-type layer 155 in the transfer direction of electric charge is controlled by the position control in the parallel direction relative to the silicon substrate 151. As a result, the fluctuation of the individual potential barrier formed in the P-type layer 155 is reduced, and the variation of the saturation electric charge amount of the individual photo diode 121 is reduced.

### (Third Example of Manufacturing Method of Pixel)

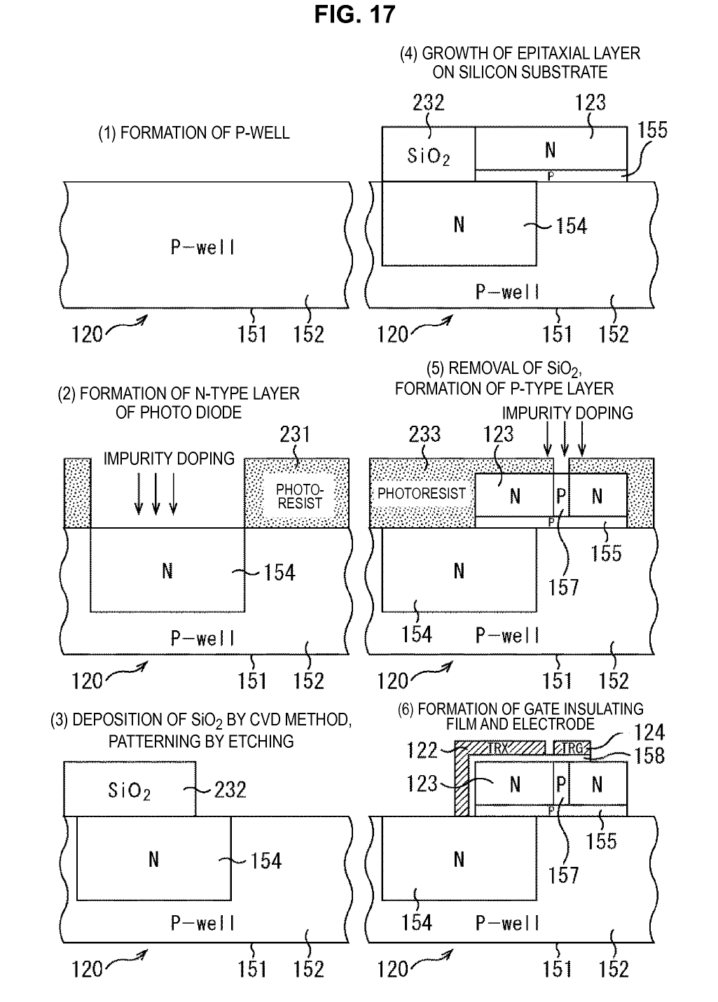

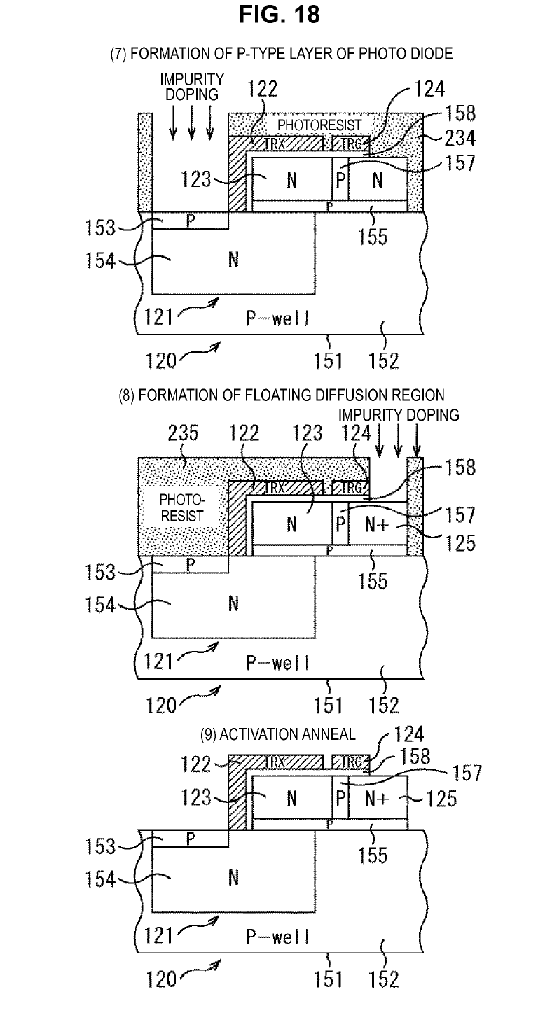

With reference to FIGS. 17 and 18, the third example of the manufacturing method of the pixel 120 by the manufacturing equipment will be described

The manufacturing method of FIGS. 17 and 18 is different from the manufacturing method of FIGS. 13 and 14 in that the epitaxial layer is not grown in the entire region on the silicon substrate 151, but only the epitaxial layer that constitutes the P-type layer 155 and the memory unit 123 is grown.

Specifically, as illustrated in FIG. 17, first, the first process and the second process are performed in the same way as FIG. 13.

In the third process, a SiO2 layer 232 is deposited on the silicon substrate 151, by the CVD method. Then, the SiO2 layer 232 of the region of the P-type layer 155 and the memory unit 123 is etched using a photoresist or the like as a mask.

In the fourth process, the P-type layer 155 and the memory unit 123 are formed as an epitaxial layer, in the region where the SiO2 layer 232 is not deposited on the silicon substrate 151, by the epitaxial growth method. The thickness of the epitaxial layer is equal to or larger than 100 nm, for example.

In the fifth process, the SiO2 layer 232 is etched using a photoresist or the like as a mask, and thereby a raised step is formed on the silicon substrate 151. Then, the P-type layer 157, the P-type layer 171, the P-type layer 174, and the P-type layer 177, which have an impurity concentration of 10¹⁶/cm³ to 10¹⁸/cm³, are formed, in the memory unit 123, by ion doping using a photoresist 233 as a mask.

The sixth to ninth processes are same as the sixth to ninth processes of FIGS. 13 and 14, and therefore their description will be omitted.

As described above, in the manufacturing method of FIGS. 17 and 18, the impurity concentration of the P-type layer 155 in the transfer direction of electric charge is controlled by the thickness and the concentration of the epitaxial layer. Thereby, the impurity concentration of the P-type layer 155 in the transfer direction of electric charge is controlled highly accurately, as compared with the case in which the impurity concentration of the P-type layer 155 in the transfer direction of electric charge is controlled by the position control in the parallel direction relative to the silicon substrate 151. As a result, the fluctuation of the individual potential barrier formed in the P-type layer 155 is reduced, and the variation of the saturation electric charge amount of the individual photo diode 121 is reduced.

Although, in the pixel 120 of FIG. 2, the light is illuminated from the front face side of the silicon substrate 151 the light may be illuminated from the back face side. That is, the pixel 120 may be a pixel of a back face illumination type. The concept of the back face illumination type is disclosed in JP 2003-31785A and other literature, for example.

### (Second Exemplary Configuration of Pixel)

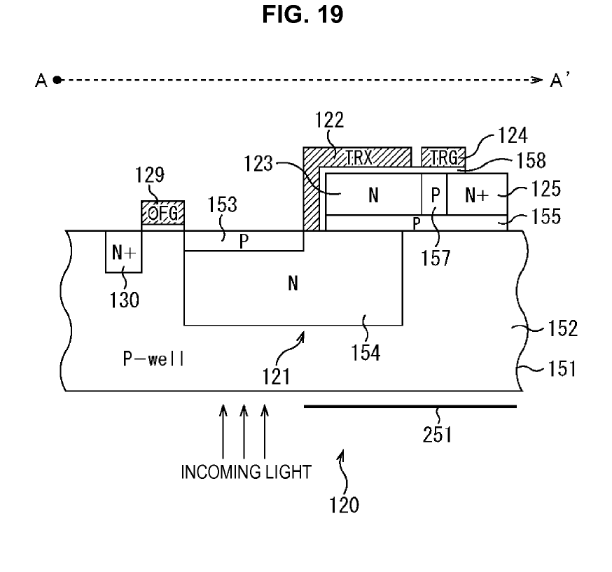

FIG. 19 is the A-A′ cross-sectional view of the pixel 120 when the pixel 120 is a pixel of the back face illumination type.

The same reference signs are assigned to the same elements, among the elements illustrated in FIG. 19, as the elements of FIG. 3. Repetitive descriptions will be omitted as appropriate.

The pixel 120 of FIG. 19 is different from the configuration of FIG. 3 in that the first transfer gate 122 and the second transfer gate 124 are not covered by the shading film 156, but the region of the back face of the silicon substrate 151 opposite to the memory unit 123 is covered by a shading film 251 made of a metal layer such as tungsten.

The pixel 120 of FIG. 19 is a pixel of the back face illumination type, and therefore light collection is not limited by the shading in the metal line layer (not depicted) located at the front face of the silicon substrate 151.

### <Exemplary Configuration of Second Embodiment>

### (Exemplary Configuration of Second Embodiment of Solid-State Image Sensor)

The configuration of the second embodiment of the CMOS image sensor as the solid-state image sensor to which the present disclosure is applied is same as the configuration of the CMOS image sensor 100 of FIG. 1 except the configuration of the pixel, and therefore only the pixel is described in the following.

### (First Exemplary Configuration of Pixel)

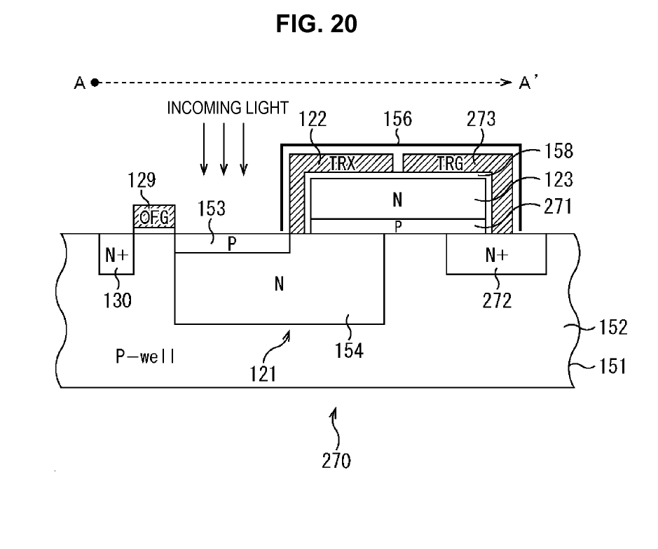

FIG. 20 is the A-A′ cross-sectional view illustrating the first exemplary configuration of the pixel of the second embodiment of the CMOS image sensor as the solid-state image sensor to which the present disclosure is applied.

The same reference signs are assigned to the same elements, among the elements illustrated in FIG. 20, as the elements of FIG. 3. Repetitive descriptions will be omitted as appropriate.

The pixel 270 of FIG. 20 is different from the configuration of FIG. 3 in that a P-type layer 271 is provided instead of the P-type layer 155 and the P-type layer 157, and that a floating diffusion region 272 and a second transfer gate 273 are provided instead of the floating diffusion region 125 and the second transfer gate 124. In the pixel 270 of FIG. 20, the floating diffusion region 272 and the memory unit 123 are located in the perpendicular direction to the silicon substrate 151, and the transfer direction of electric charge from the memory unit 123 to the floating diffusion region 272 is the perpendicular direction to the silicon substrate 151.

Specifically, as illustrated in FIG. 20, the P-type layer 271 is located on the silicon substrate 151 in which the N-type layer 154 is embedded, and at the under layer of the memory unit 123. The floating diffusion region 272 is embedded in the inner portion of the silicon substrate 151 in contact with the P-type layer 271. Also, the second transfer gate 273 is formed to cover the front face and the side face of the P-type layer 155 and the memory unit 123, via the gate insulating film 158.

The P-type layer 271 has the functions of the P-type layer 157 and the P-type layer 155. That is, the side face of the P-type layer 271 functions as a transfer path for transferring the electric charge accumulated in the photo diode 121 to the memory unit 123 when the transfer pulse is applied to the first transfer gate 122, and functions as a transfer path for transferring the electric charge accumulated in the memory unit 123 to the floating diffusion region 272 when the transfer pulse is applied to the second transfer gate 273.

Thus, the electric charge accumulated in the photo diode 121 is transferred to the memory unit 123 via the P-type layer 271, and the electric charge retained in the memory unit 123 is transferred to the floating diffusion region 272 via the P-type layer 271.

As described above, in the pixel 270, all upper portion of the P-type layer 271 is used as the memory unit 123, and therefore the electric charge amount that can be retained in the memory unit 123 increases as compared with the pixel 120.

### (Transfer Flow of Electric Charge)

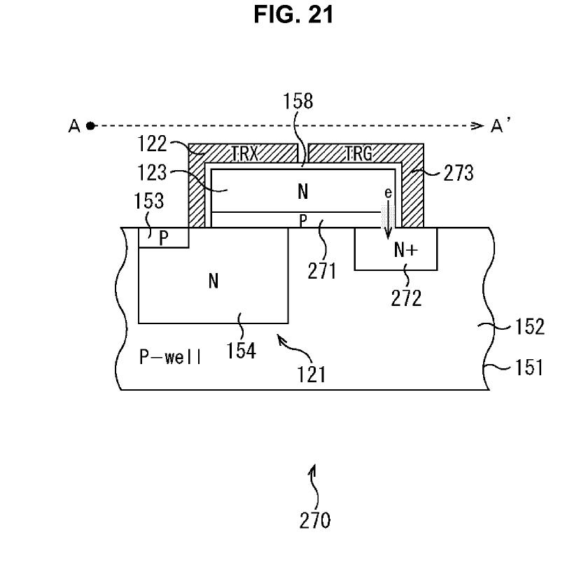

FIG. 21 is a diagram illustrating the transfer flow of electric charge from the memory unit 123 to the floating diffusion region 272.

When a negative voltage necessary for accumulating electron holes on the front face and the side face of the floating diffusion region 272 is applied to the second transfer gate 273, a potential barrier is formed by the P-type layer 271, and the interconnection between the memory unit 123 and the floating diffusion region 125 changes into a non-conductive state. Thereby, the memory unit 123 and the floating diffusion region 272 are separated electrically.

On the other hand, as illustrated in FIG. 21, when the transfer pulse is applied to the second transfer gate 273, an inversion layer is formed at the side face of the P-type layer 271, and the interconnection between the memory unit 123 and the floating diffusion region 272 changes into a conductive state. Thereby, the electric charge accumulated in the memory unit 123 is transferred in the perpendicular direction to the silicon substrate 151, and is supplied to the floating diffusion region 272.

### (Example of Manufacturing Method of Pixel)

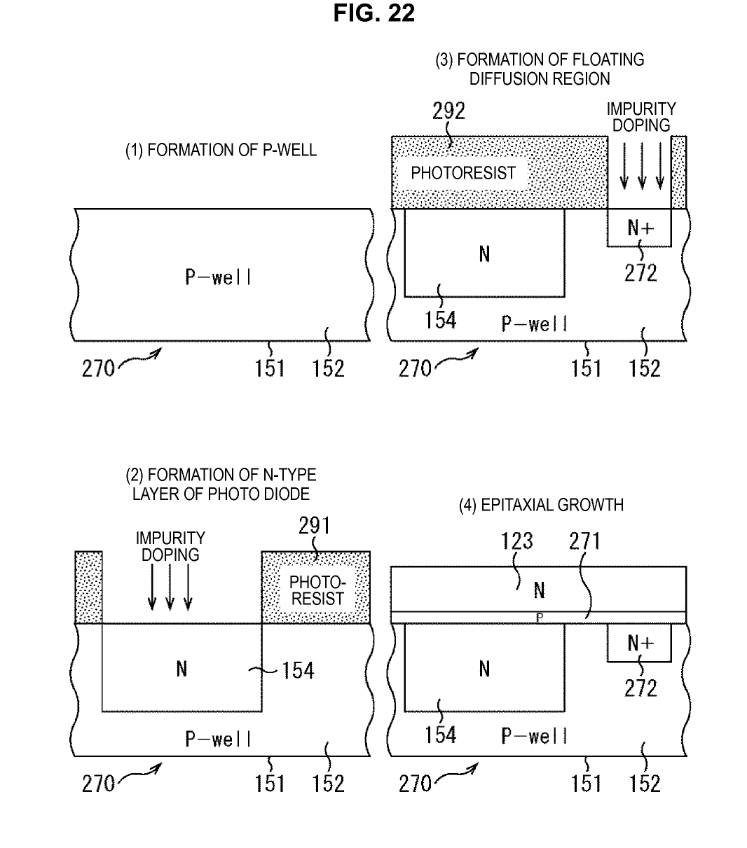

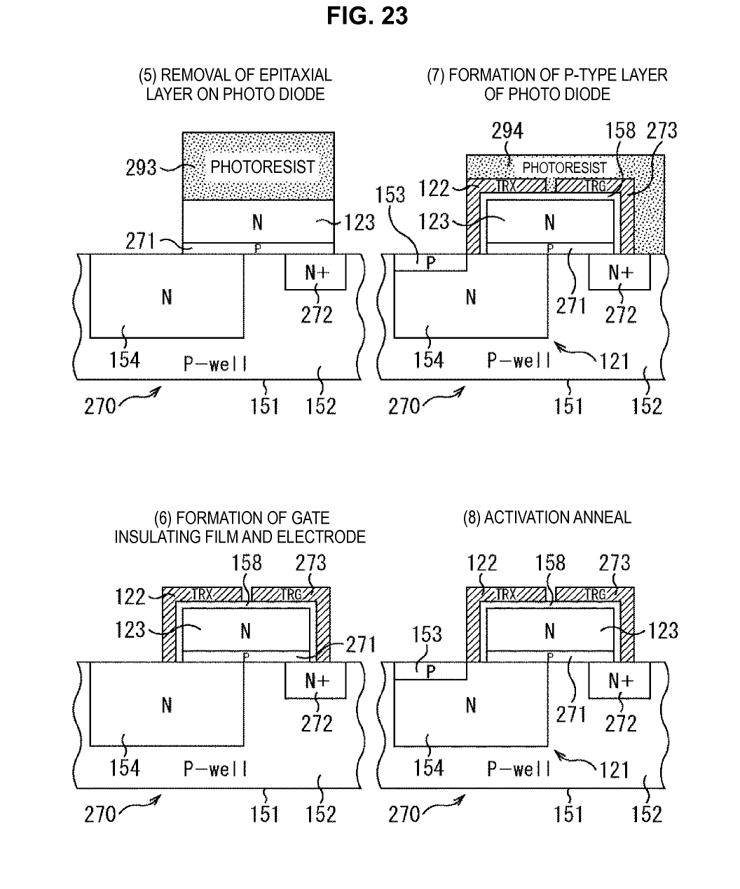

With reference to FIGS. 22 and 23, an example of the manufacturing method of the pixel 270 by the manufacturing equipment will be described

As illustrated in FIG. 22, first, the first process and the second process are performed in the same way as FIG. 13.

In the third process, an N-type layer is formed as the floating diffusion region 272 at the inner portion of the silicon substrate 151, by ion doping using a photoresist 292 as a mask.

In the fourth process, the P-type layer 271 and the memory unit 123 are formed as an epitaxial layer on the silicon substrate 151 by the epitaxial growth method, in the same way as the third process of FIG. 13.

As illustrated in FIG. 23, in the fifth process, the epitaxial layer of the region including a part of the upper portion of the N-type layer 154 and the floating diffusion region 272 is etched, using a photoresist 293 as a mask, and a raised step is formed on the front face of the silicon substrate 151.

In the sixth process, the gate insulating film 158 made of SiO2 is formed on the silicon substrate 151, by the thermal oxidation method. Then, polysilicon and metal are deposited by the CVD method on the gate insulating film 158, and the etching is performed using the resist mask, to form the first transfer gate 122, the second transfer gate 273, the gate 173, the gate 176, and the gate 179. The film thicknesses of these gates are 100 nm to 300 nm,

The seventh process is same as the seventh process of FIG. 14, and the eighth process is same as the ninth process of FIG. 14, and therefore their description will be omitted.

Note that, although not depicted, the P-type layer 271 and the memory unit 123 may be formed by ion doping in the same way as the case of FIGS. 15 and 16. Also, only the epitaxial layer that constitutes the P-type layer 271 and the memory unit 123 may be grown in the same way as the case of FIGS. 17 and 18.

As described above, in the pixel 270, the photo diode 121, the memory unit 123, the floating diffusion region 272, and the P-type layer 271 are located in the perpendicular direction to the silicon substrate 151. Thus, not only the transfer direction of electric charge between the photo diode 121 and the memory unit 123, but also the transfer direction of electric charge between the memory unit 123 and the floating diffusion region 272 is perpendicular to the silicon substrate 151.

Thereby, the impurity concentration in the transfer direction of electric charge, not only between the photo diode 121 and the memory unit 123, but also between the memory unit 123 and the floating diffusion region 272 is controlled by the thickness and the concentration of the P-type layer 271. That is, in the manufacturing method of FIGS. 22 and 23, the impurity concentration in the transfer direction is controlled by the thickness and the concentration of the epitaxial layer.

Thus, the impurity concentration in the transfer direction of electric charge, not only between the photo diode 121 and the memory unit 123, but also between the memory unit 123 and the floating diffusion region 272 is controlled highly accurately. As a result, the fluctuation of the individual potential barrier, not only between the photo diode 121 and the memory unit 123, but also between the memory unit 123 and the floating diffusion region 272 is reduced.

Note that, in the pixel 270 of FIG. 20 as well, light may be illuminated from the back face side of the silicon substrate 151. That is, the pixel 270 may be a pixel of the back face illumination type.

### (Second Exemplary Configuration of Pixel)

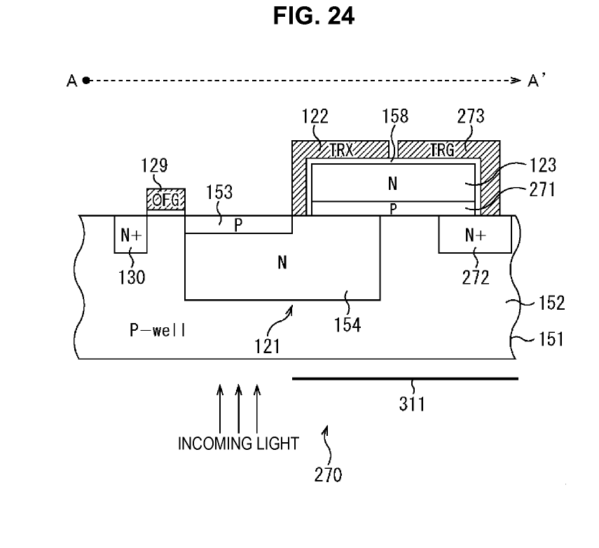

FIG. 24 is the A-A′ cross-sectional view of the pixel 270 when the pixel 270 is a pixel of the back face illumination type.

The same reference signs are assigned to the same elements, among the elements illustrated in FIG. 24, as the elements of FIG. 20. Repetitive descriptions will be omitted as appropriate.

The pixel 270 of FIG. 24 is different from the configuration of FIG. 20 in that the first transfer gate 122 and the second transfer gate 273 are not covered by the shading film 156, but the region of the back face of the silicon substrate 151 opposite to the memory unit 123 is covered by the shading film 311 made of a metal layer such as tungsten.

### <Exemplary Configuration of Third Embodiment>

### (Exemplary Configuration of Third Embodiment of Solid-State Image Sensor)

The configuration of the third embodiment of the CMOS image sensor as the solid-state image sensor to which the present disclosure is applied is same as the CMOS image sensor 100 of FIG. 1 except the configuration of the pixel, and therefore only the pixel is described in the following.

### (Exemplary Configuration of Pixel)

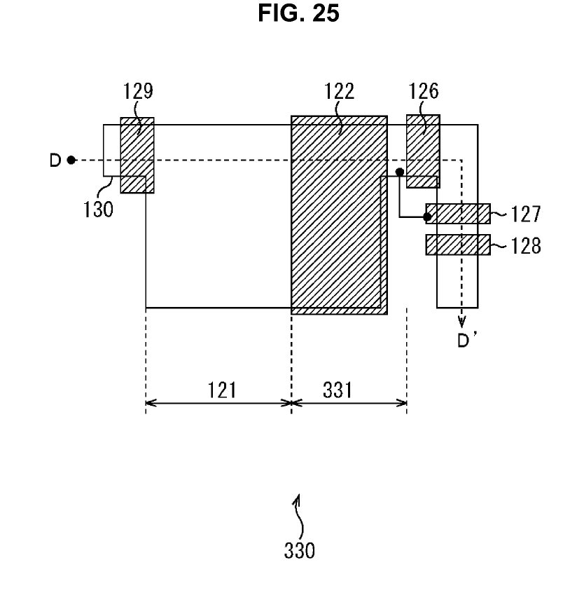

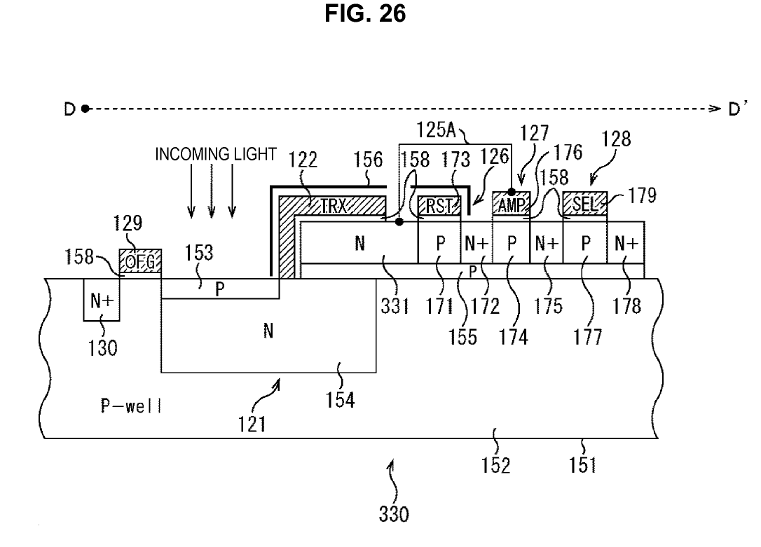

FIG. 25 is a plan view illustrating an exemplary configuration of the pixel of the third embodiment of the CMOS image sensor as the solid-state image sensor to which the present disclosure is applied, and FIG. 26 is the D-D′ cross-sectional view of the pixel of FIG. 25.

The same reference signs are assigned to the same elements, among the elements illustrated in FIG. 25 and FIG. 26, as the elements of FIG. 2 and FIG. 6. Repetitive descriptions will be omitted as appropriate.

The pixel 330 of FIG. 25 and FIG. 26 is different from the pixel 120 of FIG. 2 and FIG. 6 in that a floating diffusion region 331 is provided instead of the memory unit 123, the P-type layer 157, and the floating diffusion region 125, in order to eliminate the second transfer gate 124, and that the shading film 156 covers the first transfer gate 122 and the gate 173. In the pixel 330, the memory unit 123 and the floating diffusion region 125 are unified as the floating diffusion region 331.

Specifically, in the pixel 330, the light exposure is started in the same way as the pixel 120, and the selection pulse SEL is applied to the selection transistor 128 of the selected row by the vertical drive unit 112 immediately before the end of the light exposure, and the reset pulse RST is applied to the reset transistor 126. Thereby, the signal corresponding to the electric charge retained in the floating diffusion region 331 is output to the column processing unit 113 as an offset component of the pixel signal.

Then, the transfer pulse is simultaneously applied to the first transfer gates 122 of all pixels by the vertical drive unit 112, in the same way as the pixel 120, at the light exposure end time. Thereby, the P-type layer 155 changes into a conductive state, and the electric charge accumulated in the photo diode 121 is transferred to the floating diffusion region 331 via the P-type layer 155 and is retained. The floating diffusion region 331 converts the retained electric charge to the voltage.

Thereafter, the reset pulse RST is not applied to the reset transistor 126 of the selected row by the vertical drive unit 112, and therefore the amplification transistor 127 amplifies the voltage of the floating diffusion region 331 connected to the gate 176. In this case, the selection pulse SEL keeps being applied to the selection transistor 128, and the signal of the voltage amplified by the amplification transistor 127 is output to the column processing unit 113, as the pixel signal.

As described above, the pixel signal of the image for which the global light exposure is performed is supplied to the column processing unit 113 row by row. As a result, the pixel signal of the image for which the global light exposure is performed is output to the signal processing unit 118 in the order of raster scan.

Note that the manufacturing method of the pixel 330 is same as the manufacturing method of the pixel 120, and therefore the detailed description and depiction will be omitted.

Specifically, in the manufacturing method of the pixel 330, the first and second processes of FIG. 13 are performed, and in the third process, the P-type layer 155 and the floating diffusion region 331 are formed in the same way as the third process of FIG. 13, for example. Then, in the fourth process, the P-type layer 155 and the floating diffusion region 331 are etched in the same way as the fourth process of FIG. 13, and in the fifth process, the P-type layer 171, the P-type layer 174, and the P-type layer 177 are formed in the same way as the fifth process of FIG. 13.

Then, in the sixth process, the first transfer gate 122, the gate 173, the gate 176, and the gate 179 are formed in the same way as the sixth process of FIG. 13, and the seventh process of FIG. 13 is performed. In the eighth process, parts of the floating diffusion region 331 become the N-type layer 172, the N-type layer 175, and the N-type layer 178, and the ninth process of FIG. 13 is performed. Thereafter, the front face and the side face of the first transfer gate 122 and the gate 173 are covered by the shading film 156, to complete the manufacturing of the pixel 330.

Also, although not depicted, the pixel 330 may be a pixel of the back face illumination type. In this case, the first transfer gate 122 and the gate 173 is not covered by the shading film 156, but the region of the back face of the silicon substrate 151 opposite to the floating diffusion region 331 is covered by a shading film made of the metal layer such as tungsten.

### <Exemplary Configuration of Fourth Embodiment>

### (Exemplary Configuration of One Embodiment of Electronic Device)

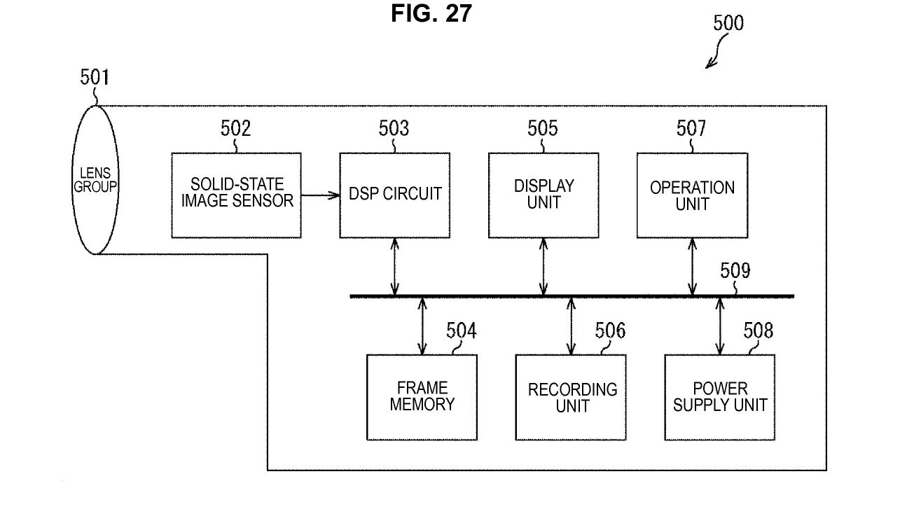

FIG. 27 is a block diagram illustrating an exemplary configuration of an image capturing device as an electronic device to which the present disclosure is applied.

The image capturing device 500 of FIG. 27 is a video camera, a digital still camera, or the like. The image capturing device 500 includes an optical unit 501, a solid-state image sensor 502, a DSP circuit 503, a frame memory 504, a display unit 505, a record unit 506, an operation unit 507, and a power supply unit 508. The DSP circuit 503, the frame memory 504, the display unit 505, the record unit 506, the operation unit 507, and the power supply unit 508 are connected to each other via a bus line 509.

The optical unit 501 is composed of lens group and others, and receives an incoming light (image light) from a subject to form an image on the imaging face of the solid-state image sensor 502. The solid-state image sensor 502 is the CMOS image sensor of the above first to third embodiments. The solid-state image sensor 502 converts the light amount of the incoming light that forms an image on the imaging face to the electrical signal with respect to each pixel by means of the optical unit 501, and supplies it to the DSP circuit 503 as the pixel signal.

The DSP circuit 503 performs a predetermined image processing to the pixel signal supplied from the solid-state image sensor 502, and supplies the image signal of each frame after the image processing to the frame memory 504, which temporarily stores it.

The display unit 505 is a panel display device, such as a liquid crystal panel and an organic electro luminescence (EL) panel, and displays an image on the basis of the pixel signal of each frame that is temporarily stored in the frame memory 504, for example.

The record unit 506 is a digital versatile disk (DVD), a flash memory, or the like, and reads and records the pixel signal of each frame that is temporarily stored in the frame memory 504.

The operation unit 507 issues an operation command with respect to various functions that the image capturing device 500 has, under the operation by the user. The power supply unit 508 supplies power to the DSP circuit 503, the frame memory 504, the display unit 505, the record unit 506, and the operation unit 507, as appropriate.

The electronic device to which the present technology is applied may be an electronic device using a solid-state image sensor as an image capturing unit (photoelectric conversion unit), which is the image capturing device 500, as well as a portable terminal device having an image capturing function, and a copy machine using a solid-state image sensor as an image read unit.

Note that the CMOS image sensor may be formed as one chip, and may be formed as a module having an image capturing function packaged including an optical unit and others.

The embodiment of the present disclosure is not limited to the above embodiments, but may be changed variously within the scope not departing from the spirit of the present disclosure.

For example, the conductivity type of the pixel may be inverted. That is, it may be such that photoelectric conversion is performed using electron holes, and an N-type well layer is formed in the silicon substrate. In this case, the memory unit is configured by a P-type layer.

Also, the impurity concentration and the film thickness are not limited to the above numerical value.

Additionally, the present technology may also be configured as below.

(1)

A solid-state image sensor including:

a substrate including

a photoelectric conversion element that generates an electric charge according to a light amount of an incoming light and accumulates the electric charge inside,

an electric charge retaining region that retains the electric charge accumulated by the photoelectric conversion element, and

a transfer path that transfers the electric charge accumulated by the photoelectric conversion element to the electric charge retaining region,

wherein the photoelectric conversion element, the electric charge retaining region, and the transfer path are located in a perpendicular direction to the substrate.

(2)

The solid-state image sensor according to (1), wherein

the photoelectric conversion element is formed in the substrate, and

the electric charge retaining region and the transfer path are formed on the substrate.

(3)

The solid-state image sensor according to (2), wherein

the substrate further includes an electric charge voltage conversion unit that converts the electric charge retained by the electric charge retaining region to a voltage.

(4)

The solid-state image sensor according to (3), wherein

the electric charge retaining region and the electric charge voltage conversion unit are located in a perpendicular direction to the substrate.

(5)

The solid-state image sensor according to (4), wherein

the electric charge voltage conversion unit is formed in the substrate.

(6)

The solid-state image sensor according to any of (2) to (5), wherein

the incoming light enters into a surface of the substrate on which the photoelectric conversion element is formed.

(7)

The solid-state image sensor according to any of (2) to (5), wherein

the incoming light enters into a surface of the substrate opposite to a surface on which the photoelectric conversion element is formed.

(8)

The solid-state image sensor according to any of (1) to (7), wherein

the electric charge retaining region converts the retained electric charge to a voltage.

(9)

A manufacturing method including:

a photoelectric conversion element formation step for forming a photoelectric conversion element that generates an electric charge according to a light amount of an incoming light and accumulates the electric charge inside, in a substrate, by means of a manufacturing equipment of a solid-state image sensor;

an electric charge retaining region formation step for forming an electric charge retaining region that retains the electric charge accumulated by a photoelectric conversion element, in the substrate, in such a manner that the photoelectric conversion element and the electric charge retaining region are located in a perpendicular direction to the substrate, by means of the manufacturing equipment of the solid-state image sensor; and

a transfer path formation step for forming a transfer path that transfers the electric charge accumulated by the photoelectric conversion element to the electric charge retaining region, in the substrate, in such a manner that the photoelectric conversion element and the transfer path are located in a perpendicular direction to the substrate, by means of the manufacturing equipment of the solid-state image sensor.

(10)

The manufacturing method according to (9), wherein

in a process of the transfer path formation step, the transfer path is formed on the substrate by an epitaxial growth method.

(11)

The manufacturing method according to (10), wherein

in the process of the transfer path formation step, the transfer path is formed on the substrate, by forming a layer on the substrate by the epitaxial growth method and removing a region other than the transfer path of the layer.

(12)

The manufacturing method according to (10), wherein

in the process of the transfer path formation step, the transfer path is formed on the substrate, by forming a layer in a region other than the transfer path on the substrate and forming a layer by an epitaxial growth method in a region where the layer is not formed.

(13)

The manufacturing method according to (9), wherein

in a process of the transfer path formation step, the transfer path is formed on the substrate, by forming the transfer path in the substrate and removing a region other than the transfer path in the substrate which is located at a same position in a perpendicular direction to the transfer path and the substrate.

(14)

An electronic device including:

a substrate including

a photoelectric conversion element that generates an electric charge according to a light amount of an incoming light and accumulates the electric charge inside,

an electric charge retaining region that retains the electric charge accumulated by the photoelectric conversion element, and

a transfer path that transfers the electric charge accumulated by the photoelectric conversion element to the electric charge retaining region,

wherein the photoelectric conversion element, the electric charge retaining region, and the transfer path are located in a perpendicular direction to the substrate.

### REFERENCE SIGNS LIST

100 CMOS image sensor,
121 photo diode,
123 memory unit,
125 floating diffusion region,
151 silicon substrate,
155 P-type layer,
271 P-type layer,
272 floating diffusion region,
331 floating diffusion region,
500 image capturing device,
502 solid-state image sensor

1. A solid-state image sensor comprising:
a substrate including
a photoelectric conversion element that generates an electric charge according to a light amount of an incoming light and accumulates the electric charge inside,
an electric charge retaining region that retains the electric charge accumulated by the photoelectric conversion element, and
a transfer path that transfers the electric charge accumulated by the photoelectric conversion element to the electric charge retaining region,
wherein the photoelectric conversion element, the electric charge retaining region, and the transfer path are located in a perpendicular direction to the substrate.

2. The solid-state image sensor according to claim 1, wherein
the photoelectric conversion element is formed in the substrate, and
the electric charge retaining region and the transfer path are formed on the substrate.

3. The solid-state image sensor according to claim 2, wherein
the substrate further includes an electric charge voltage conversion unit that converts the electric charge retained by the electric charge retaining region to a voltage.

4. The solid-state image sensor according to claim 3, wherein
the electric charge retaining region and the electric charge voltage conversion unit are located in a perpendicular direction to the substrate.

5. The solid-state image sensor according to claim 4, wherein
the electric charge voltage conversion unit is formed in the substrate.

6. The solid-state image sensor according to claim 2, wherein
the incoming light enters into a surface of the substrate on which the photoelectric conversion element is formed.

7. The solid-state image sensor according to claim 2, wherein
the incoming light enters into a surface of the substrate opposite to a surface on which the photoelectric conversion element is formed.

8. The solid-state image sensor according to claim 1, wherein
the electric charge retaining region converts the retained electric charge to a voltage.

9. A manufacturing method comprising:
a photoelectric conversion element formation step for forming a photoelectric conversion element that generates an electric charge according to a light amount of an incoming light and accumulates the electric charge inside, in a substrate, by means of a manufacturing equipment of a solid-state image sensor;
an electric charge retaining region formation step for forming an electric charge retaining region that retains the electric charge accumulated by a photoelectric conversion element, in the substrate, in such a manner that the photoelectric conversion element and the electric charge retaining region are located in a perpendicular direction to the substrate, by means of the manufacturing equipment of the solid-state image sensor; and
a transfer path formation step for forming a transfer path that transfers the electric charge accumulated by the photoelectric conversion element to the electric charge retaining region, in the substrate, in such a manner that the photoelectric conversion element and the transfer path are located in a perpendicular direction to the substrate, by means of the manufacturing equipment of the solid-state image sensor.

10. The manufacturing method according to claim 9, wherein
in a process of the transfer path formation step, the transfer path is formed on the substrate by an epitaxial growth method.

11. The manufacturing method according to claim 10, wherein
in the process of the transfer path formation step, the transfer path is formed on the substrate, by forming a layer on the substrate by the epitaxial growth method and removing a region other than the transfer path of the layer.

12. The manufacturing method according to claim 10, wherein
in the process of the transfer path formation step, the transfer path is formed on the substrate, by forming a layer in a region other than the transfer path on the substrate and forming a layer by an epitaxial growth method in a region where the layer is not formed.

13. The manufacturing method according to claim 9, wherein
in a process of the transfer path formation step, the transfer path is formed on the substrate, by forming the transfer path in the substrate and removing a region other than the transfer path in the substrate which is located at a same position in a perpendicular direction to the transfer path and the substrate.

14. An electronic device comprising:
a substrate including
a photoelectric conversion element that generates an electric charge according to a light amount of an incoming light and accumulates the electric charge inside,
an electric charge retaining region that retains the electric charge accumulated by the photoelectric conversion element, and
a transfer path that transfers the electric charge accumulated by the photoelectric conversion element to the electric charge retaining region,
wherein the photoelectric conversion element, the electric charge retaining region, and the transfer path are located in a perpendicular direction to the substrate.
